(19) United States
(12) Patent Application Publication
(10) Pub. No.: US 2009/0115026 A1
(43) Pub. Date: May 7, 2009

(54) SEMICONDUCTOR DEVICE HAVING THROUGH-SILICON VIAS FOR HIGH CURRENT,HIGH FREQUENCY, AND HEAT DISSIPATION

(75) Inventors: Mark Gerber, Lucas, TX (US); Gene Alan Frantz, Sugar Land, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/934,860

(22) Filed: Nov. 5, 2007

(51) Int. Cl. H01L 29/40; H01L 21/02

(52) U.S. Cl. 257/621; 438/122; 257/E29.002; 257/E21.597

(57) ABSTRACT

An integrated circuit device (100) with a semiconductor chip (101) having vias (103) two-dimensionally arrayed across the chip area. The metal-filled via core is suitable for electrical power and ground and heat dissipation, or for high frequency signals; at the top, the core is connected to transistors (102), and at the bottom to a metal stud (420.) The device further has a two-dimensional planar array of substantially identical metallic pads (120) separated by gaps (123, 223.) The array has two sets of pads: The first pad set (124) is located in the array center under the chip; the pad locations match the vias and each pad is in contact with the stud of the respective via. The second pad set (125) is located at the array periphery around the chip; these pads have bond wires (150) to a respective transistor terminal. Encapsulation compound (110) covers the chip and the wire connections, and fills the gaps between the pads.

### FIELD OF THE INVENTION

The present invention is related in general to the field of semiconductor devices and processes, and more specifically to structure and processes of a packaged device with chips having metal-filled vias suitable for high electrical current and frequency, and effective dissipation of thermal energy.

### DESCRIPTION OF RELATED ART

The long-term trend in semiconductor technology to double the functional complexity of its products, especially integrated circuits (ICs) every 18 months (Moore's “law”) has several implicit consequences. First, the higher product complexity should largely be achieved by shrinking the feature sizes of the chip components while holding the package dimensions constant; preferably, even the packages should shrink. Second, the increased functional complexity should be paralleled by an equivalent increase in reliability of the product. Third, the cost per functional unit should drop with each generation of complexity so that the cost of the product with its doubled functionality would increase only slightly.

As for the challenges raised by these trends in semiconductor chip construction, known technology imposes a number of limitations and problems on IC and leadframe design. Placing the high frequency and power and ground input/output terminals around the chip periphery contributes to the present difficulties to interconnect active circuit components without lengthy electrical power lines, to reduce voltage drops along the power distribution lines to distribute high frequency lines in shielded lines, and to discharge an incidental electrostatic overcharge to ground potential. Using wire bonding as the exclusive interconnection technology and placing a high number of bond pads around the chip periphery constrains possibilities to reduce voltage drops, to reduce electrical resistance and inductance, to shrink the bond pad pitch; and to save precious silicon real estate. Pre-fabricating conventional leadframes of ever increasing numbers of leads causes the ongoing difficulties to shrink the width of the inner leads, to shrink the pitch of the inner leads, and to place the stitch bonds on the minimized inner leads.

As for the challenges in semiconductor packaging, known technology imposes limitations on options to shrink the package outline so that the package consumes less area and less height when it is mounted onto the circuit board; to reach these goals with minimum cost (both material and manufacturing cost); to provide a high number of input/output terminals; to improve heat dissipation, especially to conceive of short thermal paths to reduce the elevated temperature of hot spots during IC operation; and to design packages so that stacking of chips and/or packages becomes an option to increase functional density and reduce device thickness.

### SUMMARY OF THE INVENTION

Applicants conducted an investigation including design, processes, metallurgy, reliability, and thermal performance of semiconductor device fabrication and operation to identify solutions to the above listed difficulties. The resulting new approach achieves miniaturization of the package at higher chip input/output count, significantly enhanced electrical and thermal device performance, and reduced fabrication cost. The invention features metal-filled vias through the silicon chip to supply power, ground and shielded signals from individual package pads directly to the active IC locations; the vias employ metal studs to connect to the pads, resulting in a chip assembly parallel to the plane, in which the pads are arrayed. Further included are metal-filled vias to dissipate thermal energy from IC hot spots to individual package pads interconnected by metal studs. In addition, wire bonding connects regular signals to the IC transistors. The package is lead-less and may include an insulating polymer precursor in addition to a polymer encapsulant.

One embodiment of the invention is an integrated circuit device with a semiconductor chip having vias two-dimensionally arrayed across the chip area. The metal-filled via core is suitable for electrical power and ground and heat dissipation, or for high frequency signals; at the top, the core is connected to transistors, and at the bottom to a metal stud. The device further has a two-dimensional planar array of substantially identical metallic pads separated by gaps. The array has two sets of pads: The first pad set is located in the array center under the chip; the pad locations match the vias and each pad is in contact with the stud of the respective via. The second pad set is located at the array periphery around the chip; these pads have bond wires to a respective transistor terminal. Encapsulation compound covers the chip and the wire connections, and fills the gaps between the pads.

Another embodiment of the invention is a method for fabricating an integrated circuit device comprising the steps of: In a semiconductor chip, a two-dimensional array of vias is formed across the chip area so that each via extends from the top to the bottom chip surface and has an insulating coat and a metal-filled core suitable for electrical power and ground, and heat dissipation, or alternatively for high frequency signal transmission. On a chip metallization level, or on the top chip surface, connections are made from the vias to the transistors, and on the bottom chip surface, a metal stud is formed for each via; the studs have substantially equal heights.

In order to fabricate a two-dimensional planar array of metallic pads, a metallic sheet with a thickness is provided and a grid of grooves is formed into one sheet surface. The grooves are terminated at a depth before reaching the opposite sheet surface, resulting in a two-dimensional array of metallic pads attached on a solid metallic sheet. The array includes a first set of pads in the array center at locations matching the vias, and a second set of pads at the array periphery. The via studs are attached to the center pad set; the chip transistors are wire connected to the peripheral pad set. Using encapsulation compound, the chip and the wire connections are covered and the grooves between the pads are filled. Finally, the bottom surface of the metallic sheet is removed, whereby the compound-filled grooves are exposed and a bottom surface of the metallic pads is formed.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1A illustrates schematically an embodiment of the invention in perspective view; a packaged semiconductor device is partially opened to show the chip with metal-filled vias and redistribution traces assembled by metal studs and wires on a two-dimensional array of metallic pads separated by gaps, the pads supported by an insulating carrier.

FIG. 1B illustrates schematically an embodiment of the invention in perspective view; a packaged semiconductor device is partially opened to show the chip with metal-filled vias and redistribution traces assembled by metal studs and wires on a two-dimensional array of metallic pads separated by gaps.

FIG. 2 shows a schematic cross section of another embodiment of the invention, wherein the array of metallic pads is fabricated by another technique than in FIG. 1.

FIG. 3 is a schematic perspective view of a portion of the semiconductor chip showing detail of the array of vias and redistribution traces.

FIG. 4 is a schematic cross section of a metal-filled via through the semiconductor chip and the attached metal stud.

FIG. 5A is a schematic cross section of another embodiment showing a stack of chips with metal-filled vias assembled on metallic pads by metallic studs and wires.

FIG. 5B is an embodiment similar to FIG. 5A with redistribution traces from the vias to the metal studs.

FIG. 6A is a schematic cross section of another embodiment showing a chip with metal-filled vias assembled by metal studs on metallic pads.

FIG. 6B is an embodiment similar to FIG. 6A with redistribution traces from the vias to the metal studs.

### DETAILED DESCRIPTION OF THE PREFERRED EMBODIMENTS

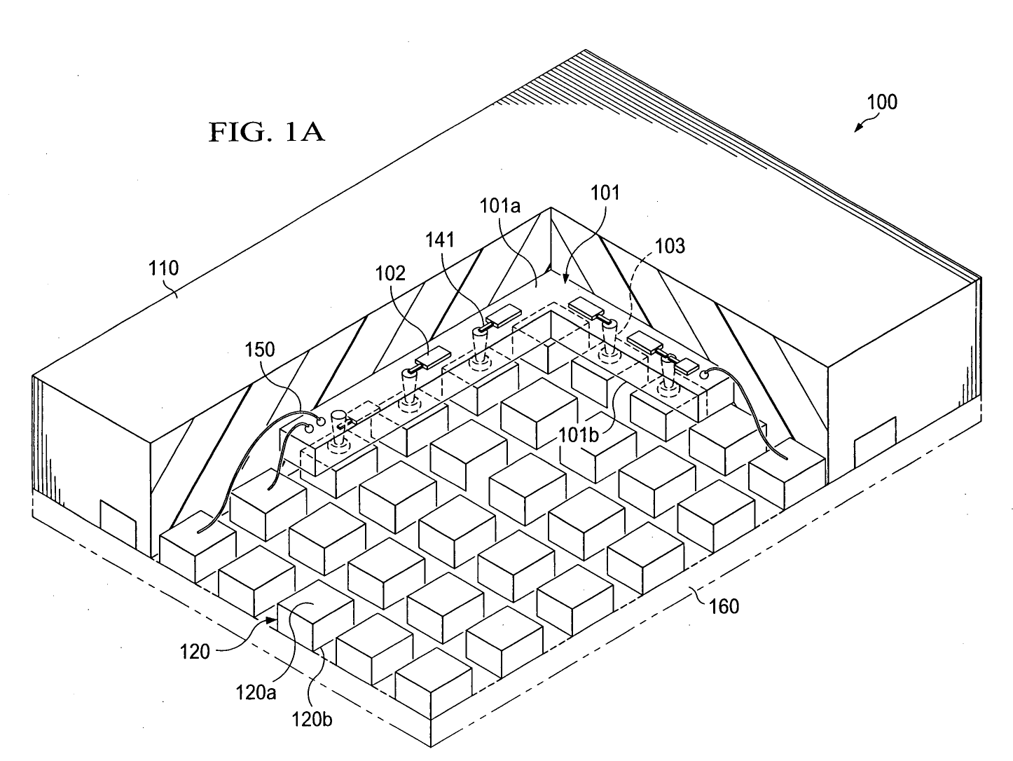

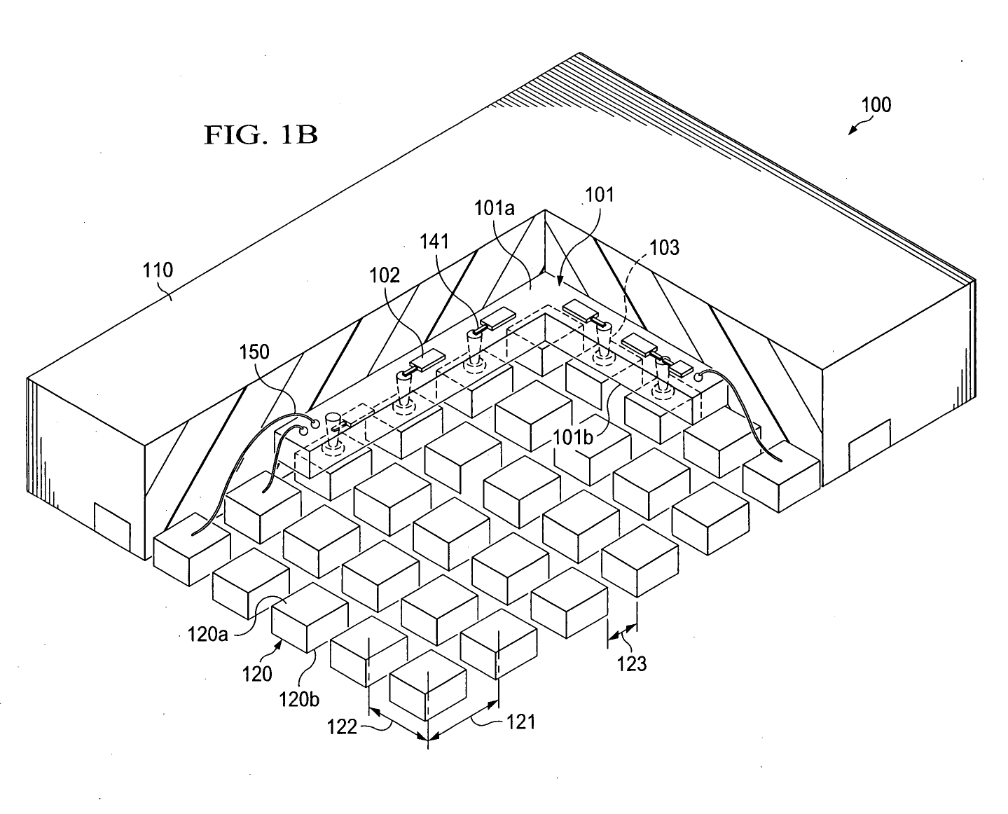

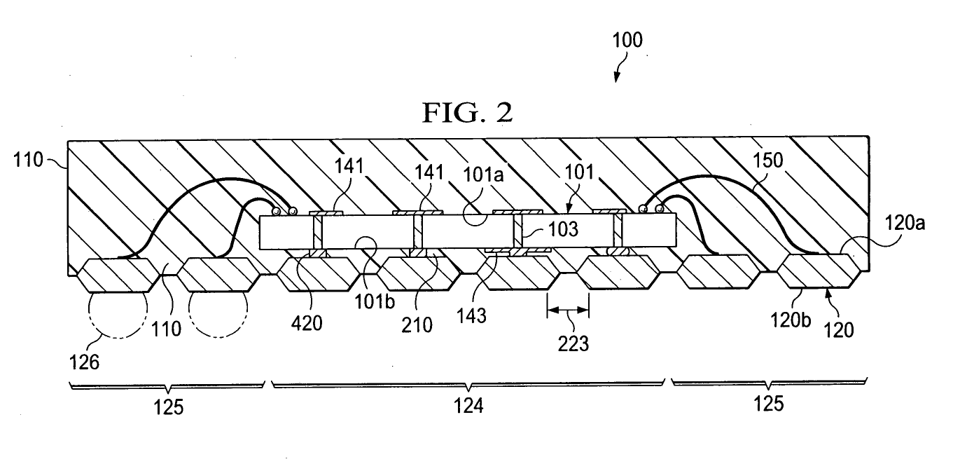

An embodiment of the invention illustrated in FIGS. 1A and 1B in cut-open perspective view and in FIG. 2 in cross sectional view, is a packaged integrated circuit device generally designated 100 in FIGS. 1A and 1B. The device includes a semiconductor chip 101 encapsulated in protective compound 110, and a two-dimensional area array of contact pads 120 with one pad surface 120b free of compound. The semiconductor chip 101 has an area, a top surface 101a, which includes transistors or other circuit components 102, and a bottom surface 101b free of transistors.

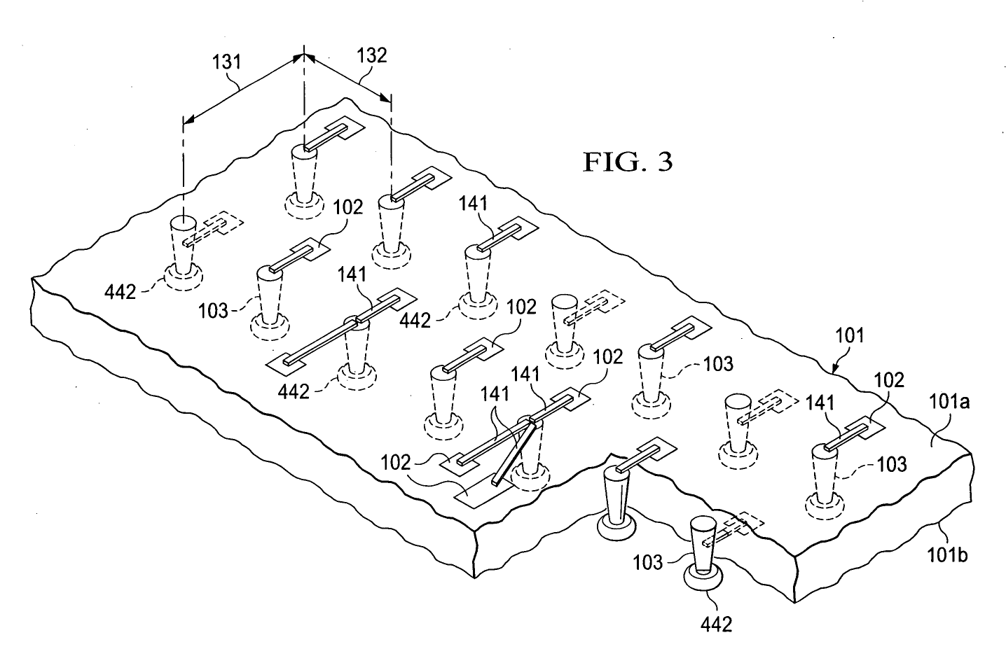

Throughout the chip area are vias 103, two-dimensionally arrayed. The two-dimensional arrangement is also depicted in FIG. 3. The via array may be random, but preferably, the via arrangement is substantially uniform so that the vias have a pitch center-to-center, which is designated 131 in the x-direction, and 132 in the y-direction. In many embodiments, the pitches are constant, and in some embodiments, pitch 131 is the same as pitch 132, while in other embodiments (as shown in FIG. 3), the pitches are different from each other. Please note that via pitch 131 is preferably the same as pitch 121 of the contact pads 120, and via pitch 132 the same as pad pitch 122, but in some embodiments they are not identical.

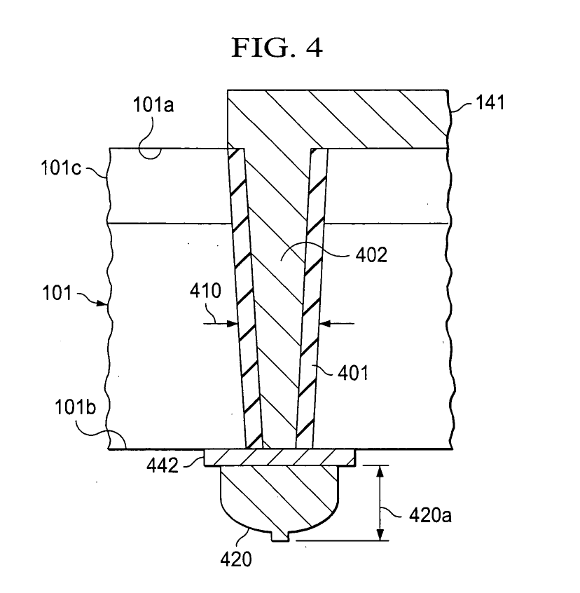

Each via 103 of the two-dimensional array across the chip area extends from the top chip surface 101a to the bottom chip surface 101b. The vias are, therefore, often referred to as through-semiconductor-vias (TSVs.) As shown in the magnified cross section in FIG. 4, each via 103 has a wall covered by an insulating layer (coat) 401. The core of the via is filled with metal 402, preferably copper, or other suitable conductive material. The diameter 410 of the via is selected so that the core has a low electrical resistance and inductance to carry electrical power and ground, and also a low thermal resistance to dissipate heat from circuit hot spots. Via diameter 410 has an opening of a preferably circular cross section or a geometrical cross section given by the crystalline orientations of the semiconductor. For a cylinder-shaped via, diameter 410 is constant over the via length. The preferred diameters are between about 3 and 50 μm. Since the amount of metal in the via core determines the size of the difference in the coefficient of thermal expansion (CTE) relative to the semiconductor material, vias with small diameters are preferred. For silicon, its CTE dominates the metal CTE in vias with diameters smaller than about 30 μm.

Any place along its extension and especially n the top chip surface 101a (actually the surface of the protective overcoat 101c), via 103 has one or more connections or routing traces 141 (preferably copper) to one or more particular transistors or other circuit components 102. Traces 141 may be direct connections, as shown in FIG. 3, or they may be connections by detours using other chip metallization levels. On the bottom chip surface 101b, via 103 may have a metal terminal 442 (preferably copper with a bondable surface) together with a metal stud 420. The stud is preferably fabricated as a coined gold ball (alternatively as a coined copper ball) by a wire ball bonding technique (see below.) Alternatively, a micro-bump technology or a plating process can be used, especially for batch processing. The method produces substantially equal heights 420a of the studs 420 so that the attachment of chip 101 to the pads 120, using studs 420 provides uniform spacing between the chip and the planar array of pads 120.

For some embodiments, it is advantageous to employ additional redistribution lines, preferably made of copper, on the bottom surface 101b of the chip, as indicated schematically by lines 143 in FIG. 2. These redistribution lines may be used in some embodiments, such as stacked-chip and flip-assembly-only devices, to restrict the vias to the chip periphery regions.

Alternatively, at least some vias 103 may be formed as electrically shielded vias suitable to transmit high frequency signals. In addition, some vias 103 may be designed with short traces 141 to circuit inputs/outputs to effectively discharge to ground potential any electrostatic overcharge in overstress events.

Additional metal-filled vias may be placed in close proximity to circuit spot, where, according to modeling or experience, high frequency and intense circuit integration are causing extraordinary temperature increases during circuit operation. These additional vias offer direct, short-cut paths for heat dissipation from the circuit to external heat sinks and thus keep the device operating reliably in safe temperature regions.

Referring to FIGS. 1A, 1B, and 2, device 100 includes a two-dimensional planar array of metallic pads 120 separated by gaps. In FIG. 1A, the pads are supported by a carrier 160, which may be made of insulating material or a laminated carrier. Carrier 160 is shown in dashed outline, because it is employed during the device assembly processes (see below) and subsequently removed. In FIG. 1B, the pads have been prepared without support (see below.) The gaps in FIGS. 1A and 1B, designated 123, have straight sidewalls of the pads; the gaps in FIG. 2, designated 223, have pad sidewalls shaped as truncated grooves adjoining at the truncated portion. The difference of the gap shapes is a consequence of the method employed for fabricating the pads; see below. The pads are preferably substantially identical and have a pitch center-to-center, which is designated 121 in the x-direction and 122 in the y-direction. In many embodiments (as shown in FIGS. 1A and 1B), pitch 121 is the same as pitch 122, while in other embodiments, the pitches are different from each other. Preferably, the pad x- and y-pitches are the same as the corresponding via x- and y-pitches, but in some embodiments they are not identical (for example, compare FIGS. 1A and 1B with FIG. 3.)

Pads 120 have a first surface 120a facing towards the chip 101 and a second surface 120b facing away from chip 101. As FIGS. 1A, 1B, and 2 shows, the planar array of pads 120 is composed of two sets: The first pad set, designated 124, is located in the array center and is under the chip. The pad locations of set 124 match the corresponding vias 103, and preferably each pad of this set is in contact with the metallic stud 420 of the respective via. In this fashion, the electrical path from the second pad surface 120b through stud 420, via 103, and connection 141 to the transistor has minimum electrical resistance and inductance for electrical power and ground potential, and minimum thermal resistance for heat dissipation. Further, the path offers itself to effective discharge of electrostatic overcharge to ground potential. On the other hand, when vias 103 are electrical shielded, the path from the second pad surface 120b through stud 420, via 103, and connection 141 offers itself the high frequency signal transmission.

The second pad set, designated 125, is located at the array periphery and is surrounding the chip. Preferably each pad of this set has at least one bond wire 150 to a respective transistor terminal of the integrated circuit on chip surface 101a.

Pads 120 are preferably made of copper. First surface 120a is preferably suitable for attaching metallic studs (for example, gold or copper) and wire stitch bonds (for example, gold or copper). Second surface 120b is suitable for attachment of solder balls 126 (for instance, by having a surface of a thin gold layer). In FIG. 1A, second surface 120b is temporarily supported by carrier 160.

As FIGS. 1A, 1B, and 2 illustrate, encapsulation compound 110 covers the chip 101, the wire connections 150, and the first pad surfaces 120a. Preferably, compound 110 is an epoxy-based molding material. The second pad surfaces 120b remain free of compound 110. When the pads 120 are configured as shown in FIGS. 1A and 1B, the gaps 123 between the pads are preferably filled with compound 110. In this case, the compound surface in gaps 123 is coplanar with the second surface 120b of the pads. On the other hand, when the pads 120 are configured as shown in FIG. 2, the gaps 123 are preferably only partially filled with compound 110 (see below for the fabrication process.)

The space 210 between the bottom chip surface 101b and the first pad surface 102a of the first set pads 124 may be filled with encapsulation compound, as shown by the embodiment of FIG. 2. Alternatively, a polymerized precursor may be used to fill the space between the bottom chip surface 101b and the first pad surface 120a of the first set pads 124.

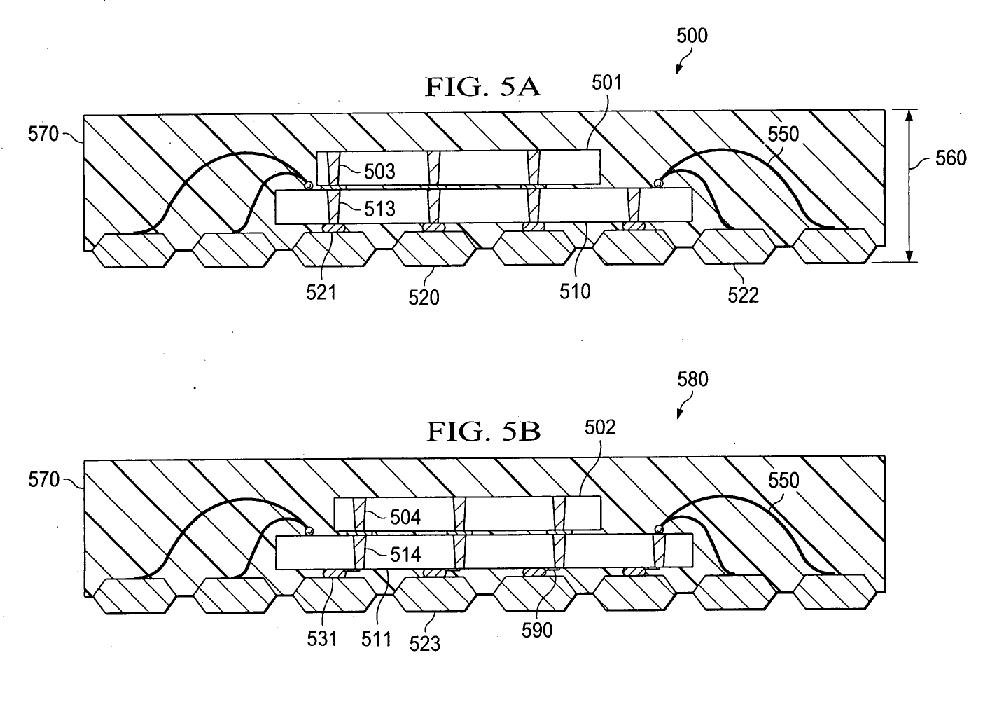

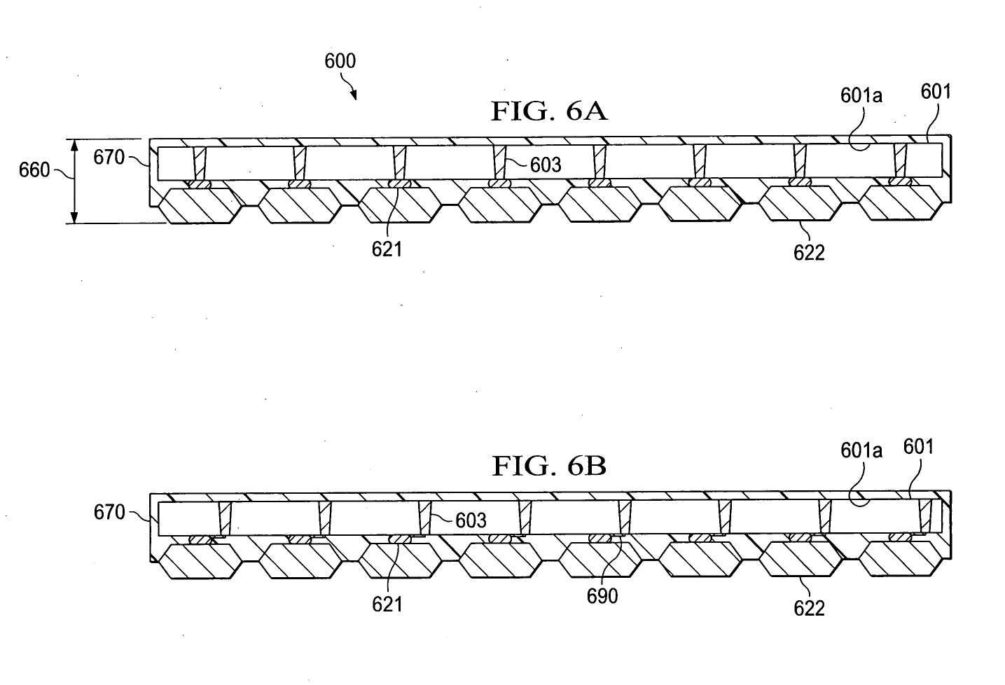

FIGS. 5A, 5B, 6A, and 6B illustrate additional embodiments, which highlight the advantages to be derived by the use of TSVs combined with metal pads in two-dimensional planar arrays. FIG. 5A shows a device 500 with two chips 501 and 510 of different sizes (areas) stacked upon each other. Chip 501 has vias 503, and chip 510 has vias 513. Vias 503 are in locations so that they can be aligned with some of the vias 513; the aligned vias are interconnected by metal studs (not shown in FIG. 5A.) Vias 513, in turn, are connected by metal studs 521 on the bottom surface of chip 510 to metallic pads 520 located under chip 510 and facing chip 510. In addition, bonding wires 550 connect metal pads 522 to transistors located on the top surface of chip 510. The stacked chips, the bonding wires, and the top surface of pads 520 and 522 are protected by encapsulation compound 570. Since automated bonders can keep the loop heights of wires 550 low, the encapsulation compound can be thin and the overall thickness 560 of device 500 may be as small as about 0.3 to 0.4 mm.

FIG. 5B shows a device 580 with stacked chips similar to device 500. The vias 504 of chip 502 are aligned with vias 514 of chip 511. Vias 514, however, need redistributing metal lines 590 in order to connect to metal studs 531. The studs 531 are in contact with metal pads 523 of the planar array of pads. Device 580 has a thickness in the range from about 0.3 to 0.4 mm.

Even smaller thicknesses can be realized in embodiments exclusively assembled by metal stud connectors, without recourse to wire bonding. FIG. 6A depicts a chip-size device 600 with a chip 601, which has a plurality of metal-filled vias 603 between the transistors on chip surface 601a and the metal studs 621; the vias 603 are aligned with the studs 621. These studs, preferably made of gold or copper, are fused onto a two-dimensional planar array of metallic pads 622. Vias 603 are designed to serve electrically as supply for power and ground, and as inputs/outputs for signals, as well as to serve thermally as heat dissipation channels. An encapsulation compound 670 protects the circuitry on chip surface 601a. The overall device thickness 660 can be kept in the range from about 0.2 to 0.3 mm. The similar device in FIG. 6B has redistribution lines 690 between vias 603 and studs 621, since the vias are not aligned with the studs. The overall thickness of the device in FIG. 6B is between 0.2 and 0.3 mm.

Another embodiment of the invention is a method for fabricating an integrated circuit device with through-silicon vias (TSVS) for high current, high frequency, and maximized heat dissipation. A semiconductor wafer is provided, which includes a plurality of chips with an area, a top surface with transistors and other circuit components, and a bottom surface free of transistors. After backgrinding, a two-dimensional array of vias is formed throughout each chip area; the array may be random, but is preferably uniform; the vias may be produced by chemical etching, laser, or plasma. In the preferred embodiment, the array of vias has a constant pitch center-to-center. Each via of the array extends from the top to the bottom chip surface and has an insulating coat and a metal-filled core, preferably made of copper (alternatively of silver, an alloy, or another suitable conductive material). The diameter of the via is selected so that the electrical and thermal conductivity of the via metal is suitable for high electrical power and ground potential, and also for effective heat dissipation.

Throughout the length of the via, and especially on the top surface of each chip, metal traces are patterned as connections from the vias to the transistors and other circuit elements. At the bottom surface of each chip, a metal stud is formed for each via. Preferably, the studs are made of gold or copper, and the preferred attachment method is a modified wire ball bonding technique combined with a coining step to achieve substantially equal heights for all studs. Alternatively, a plating technique may be used. In some embodiments, it may be advantageous to place the stud near the via instead of directly on the via exit. In this case, redistribution traces are patterned to connect the studs to the vias.

When a carrier laminated with a metal layer is used, a two-dimensional planar array of metallic pads is preferably fabricated by an etch step using masks on the metal layer on the carrier surface. (At the end of the device fabrication flow, the carrier is removed and discarded.) When the two-dimensional planar array of metallic pads is prepared without laminated carrier, the fabrication process provides a flat metallic sheet, which preferably is made of copper and has a thickness of 1 mm or less; the sheet has a first surface and a second surface.

Next, a grid of grooves is made into the first surface of the sheet. The grooves are terminated at a depth before reaching the second surface so that a two-dimensional array of metallic protrusions or pads is formed, which is attached on a solid metallic sheet-like connection. While a rotating saw blade may be used to create the grooves, the preferred technique uses a mask and chemical or plasma etching. In the preferred embodiment, the pads have the same pitch center-to-center as the chip via pitch mentioned above. In addition, in the most preferred embodiment, the grid of grooves is orthogonal.

The array of pads is grouped into sub-arrays. Each sub-array includes a first set of pads, which is located in the sub-array center and matches the chip vias, and a second set of pads, which is located at the sub-array periphery.

The wafer and the pad array on the sheet-like connection are aligned so that each chip faces the respective sub-array. The via studs are then brought into contact with the respective center pad set, and the studs are attached to the first pad surfaces. A preferred method of attachment is thermosonic bonding; alternatively, a heating and pressuring cycle may be used.

In the next process step, the transistors of each chip are connected by wire ball bonding to the first surface of the respective peripheral pad set. The wafer, the wire connections, and the first pad surfaces are then protected with an encapsulation compound. A preferred method employs a transfer molding technique. In this encapsulation step, the grooves are filled with compound, and, preferably, also the space between the bottom chip surface and the first pad surface of the first set pads is filled with compound. The solid sheet-like connection, on which the pads are attached, remains free of compound.

In embodiments, where the encapsulation compound is not filling the space between the bottom chip surface and the first pad surface, an additional underfill step may be advisable. In this step, a polymerizable precursor is used to fill, by capillary action, the space between the bottom chip surface and the first pad surface of the first set pads and to surround the metal studs.

In the next process step, the bottom surface of the metallic sheet and the connection, to which the pads are attached, is removed, whereby a fresh second surface of the metallic pads is created. The preferred method for removal is etching (chemical or by plasma); alternatively, a mechanical ablation or grinding method may be employed. Optionally, the fresh second surface (preferably copper) may be covered with a solderable layer (nickel, gold.)

After the sequence of process steps as described above, the second pad surface is coplanar with the compound surface in the grooves between the pads (see FIG. 1B.) In an alternative process flow, the step of removing the bottom surface of the metallic sheet is replaced by a sawing step. A rotating saw, applied vertically to the bottom surface of the metallic sheet, cuts additional grooves into the sheet so that the additional grooves are aligned with the grooves created earlier in conjunction with the fabrication of the pad grid. The penetration of the saw stops when the metallic connection is fully severed and the saw hits the compound. After the sawing process, the compound is exposed and recessed relative to the second pad surfaces (see FIG. 2.)

In order to enhance the contacts and connections to external parts, solder balls may be attached to the second pad surfaces (see FIG. 2.)

Finally, the encapsulated and attached wafer is singulated into discrete devices, preferably by a sawing technique.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An integrated circuit device comprising:
a semiconductor chip having an area, a top surface including transistors, and a bottom surface free of transistors;
vias two-dimensionally arrayed, substantially uniform throughout the chip area;
each via extending from the top to the bottom chip surface, having an insulating coat, a metal-filled core suitable for electrical power and ground, and heat dissipation, at the top surface having connections to the transistors, and at the bottom surface having a metal stud;
a two-dimensional planar array of metallic pads separated by gaps, the pads having a first surface facing towards the chip and a second surface facing away from the chip, the array having two sets of pads:
the first pad set located in the array center and being under the chip, the pad locations matching the vias, and each pad in contact with the stud of the respective via;
the second pad set, located at the array periphery and being around the chip, each pad having bond wires to a respective transistor terminal; and
encapsulation compound covering the chip, the wire connections, and the first pad surfaces, whereby the second pad surfaces remain free of compound.

2. The device of claim 1 further having encapsulation compound filling the gaps between the pads.

3. The device of claim 1 wherein the vias are arrayed at a constant pitch center-to-center, and the metallic pads are arrayed at the same pitch.

4. The device of claim 1 further having shielded vias suitable for high frequency signal transmission.

5. The device of claim 1 wherein the metal in the vias at ground potential discharge electrostatic overcharge events.

6. The device of claim 1 wherein the via studs at the bottom surface have substantially equal heights, and the spacing between the chip and the planar array of pads is uniform.

7. The device of claim 1 wherein the metallic pads have same shape and size.

8. The device of claim 1 further including the pads having the second surface, free of encapsulation compound, suitable for solder attachment.

9. The device of claim 1 further having the encapsulation compound filling the space between the bottom chip surface and the first pad surface of the first set pads.

10. The device of claim 1 further including a polymerizable precursor to fill the space between the bottom chip surface and the first pad surface of the first set pads.

11. The device of claim 1 wherein the semiconductor chip is a stack of semiconductor chips.

12. A method for fabricating an integrated circuit device comprising the steps of:
providing a semiconductor wafer including a plurality of chips having an area, a top surface including transistors, and a bottom surface free of transistors;
forming a two-dimensional array of vias uniformly across each chip area so that each via extends from the top to the bottom chip surface and has an insulating coat and a metal-filled core suitable for electrical power and ground, and heat dissipation, and connection to respective transistors;
attaching, at the bottom chip surface, a metal stud to each via, the studs having substantially equal heights;
forming a two-dimensional planar array of metallic pads by the steps of:
providing a metallic sheet having a thickness, a first surface and a second surface;
forming a grid of grooves into the first surface;
terminating the grooves at a depth before reaching the second surface, thereby forming a two-dimensional array of metallic pads attached on a solid metallic sheet-like connection; and
grouping the array into sub-arrays, wherein each sub-array includes a first set of pads, located in the sub-array center and matching the chip vias, and a second set of pads, located at the sub-array periphery;
aligning the wafer and the pad array so that each chip faces the respective sub-array;
bringing the via studs into contact with the respective center pad set and attaching the studs to the first pad surfaces;
wire-connecting the transistors of each chip to the first surface of the respective peripheral pad set; and
covering the wafer, the wire connections, and the first pad surfaces with an encapsulation compound.

13. The method of claim 12 wherein the array of vias has a constant pitch center-to-center.

14. The method of claim 13 wherein the pads have the same constant pitch center-to-center as the via pitch.

15. The method of claim 12 wherein the grid of grooves is orthogonal.

16. The method of claim 12 further including the step of removing the bottom surface of the metallic sheet, thereby forming a fresh second surface of the metallic pads.

17. The method of claim 16 wherein the step of removing the bottom sheet surface is performed by an etching technique or a grinding technique.

18. The method of claim 12 further including the step of singulating the wafer into discrete devices.

19. A method for fabricating an integrated circuit device comprising the steps of:
providing a semiconductor wafer including a plurality of chips having an area, a top surface including transistors, and a bottom surface free of transistors;
forming a two-dimensional array of vias substantially uniform throughout each chip area so that each via extends from the top to the bottom chip surface and has an insulating coat, a metal-filled core suitable for electrical power, ground, and heat dissipation, and connections to respective transistors;
attaching, at the bottom chip surface, a metal stud to each via, the studs having substantially equal heights;
providing a planar carrier having a metallic layer of a thickness on a surface;
forming a grid of grooves into the layer, the grooves reaching through the thickness to the carrier, thereby forming a two-dimensional array of metallic pads attached on the planar carrier; and
grouping the array into sub-arrays, wherein each sub-array includes a first set of pads, located in the sub-array center and matching the chip vias, and a second set of pads, located at the sub-array periphery;
aligning the wafer and the pad array so that each chip faces the respective sub-array;
bringing the via studs into contact with the respective center pad set and attaching the studs to the first pad surfaces;
wire-connecting the transistors of each chip to the first surface of the respective peripheral pad set;
covering the wafer, the wire connections, and the first pad surfaces with an encapsulation compound;
removing the planar carrier; and
singulating the wafer into discrete devices.
